(19) United States
(12) Patent Application Publication
(10) Pub. No.: US 2026/0189192 A1
(43) Pub. Date: Jul. 2, 2026

(54) POWER AMPLIFIER CIRCUIT, TRANSMIT CIRCUIT, AND COMMUNICATION DEVICE INCLUDING THE SAME

(71) Applicant: Murata Manufacturing Co., Ltd., Nagaokakyo-shi (JP)

(72) Inventors: Kenji TAHARA, Nagaokakyo-shi (JP); Kae Yamamoto, Nagaokakyo-shi (JP)

(21) Appl. No.: 19/546,511

(22) Filed: Feb. 23, 2026

Related U.S. Application Data
(63) Continuation of application No. PCT/JP2024/032311, filed on Sep. 10, 2024.

(30) Foreign Application Priority Data
Oct. 2, 2023 (JP) 2023-171362

(51) Int. Cl. H03F 1/02; H03F 3/24

(52) U.S. Cl. CPC H03F 1/0288; H03F 3/245; H03F 2200/06; H03F 2200/451; H03F 2200/534

(57) ABSTRACT

A power amplifier circuit includes an input terminal, amplifiers, phase shifters, a converter circuit, and an output terminal. Each of the amplifiers is configured to amplify an input signal that is a radio-frequency signal received through the input terminal. The converter circuit is configured to convert a pair of balanced lines to an unbalanced line. The output terminal is coupled to the unbalanced line. The converter circuit includes balanced terminals that are respectively coupled to corresponding ones of the pair of balanced lines. The phase shifter is coupled between the output of the amplifier and the output of the amplifier. The phase shifter is coupled between the output of the amplifier and the output of the amplifier. The phase shifter is coupled between the output of the amplifier and the balanced terminal. The output of the amplifier is coupled to the balanced terminal.

### CROSS REFERENCE TO RELATED APPLICATION

This is a continuation of International Application No. PCT/JP2024/032311 filed on Sep. 10, 2024 which claims priority from Japanese Patent Application No. 2023-171362 filed on Oct. 2, 2023. The contents of these applications are incorporated herein by reference in their entireties.

### BACKGROUND OF THE DISCLOSURE

### Field of the Disclosure

The present disclosure relates to power amplifier circuits and to transmit circuits and communication devices that include the same, and more specifically, relates to technologies for improving the efficiency of power amplifier circuits.

### Description of the Related Art

Japanese Unexamined Patent Application Publication No. 2018-137566 discloses an amplifier circuit that includes a first differential amplifier (carrier amplifier) and a second differential amplifier (peaking amplifier) that amplify signals obtained by splitting an input signal, and transformers (first transformer, second transformer) respectively provided for the corresponding differential amplifiers. The first differential amplifier operates in the region in which the input signal power level is greater than or equal to a first level, and the second differential amplifier operates in the region in which the input signal power level is greater than or equal to a second level greater than the first level. The first transformer and the second transformer receive and combine the signals outputted from the first differential amplifier and the second differential amplifier, and the combined output signal is outputted to a load.

### BRIEF SUMMARY OF THE DISCLOSURE

Applying digital envelope tracking (ET) to the supply voltage of power amplifier circuits configured as in Japanese Unexamined Patent Application Publication No. 2018-137566 improves the efficiency in the back-off region ranging from the high-power output region in which both the carrier amplifier and the peaking amplifier operate to the low-power output condition in which the carrier amplifier solely operates.

The Doherty amplifier configuration in Japanese Unexamined Patent Application Publication No. 2018-137566 and general Doherty amplifier configurations typically achieve a back-off level of 6 dB. However, the required back-off level for power amplifier circuits can vary depending on, for example, the modulation scheme, the set voltage of the digital ET, and/or the target frequency band width of the digital ET. Depending on the specifications required for the devices in which the power amplifier circuit is used, a back-off level greater than 6 dB may be necessary in certain cases.

The present disclosure has been made to solve the problem described above, and a possible benefit thereof is to provide power amplifier circuits capable of achieving a back-off level of 6 dB or higher.

A power amplifier circuit according to the present disclosure includes an input terminal, first to fourth amplifiers, first to third phase shifters, a converter circuit, and an output terminal. The first to fourth amplifiers are configured to amplify an input signal that is a radio-frequency signal received through the input terminal. The converter circuit is configured to convert a pair of balanced lines to an unbalanced line. The output terminal is coupled to the unbalanced line. The converter circuit includes a first balanced terminal and a second balanced terminal that are respectively coupled to corresponding ones of the pair of balanced lines. The first phase shifter is coupled between an output of the first amplifier and an output of the second amplifier. The second phase shifter is coupled between an output of the third amplifier and an output of the fourth amplifier. The third phase shifter is coupled between the output of the second amplifier and the first balanced terminal. The output of the third amplifier is coupled to the second balanced terminal. The second amplifier, the third amplifier, and the fourth amplifier are configured to be selectively driven based on a power level of the input signal.

The power amplifier circuit according to the present disclosure includes a Doherty circuit in which the first amplifier operates as a carrier amplifier, and the second to fourth amplifiers operate as peaking amplifiers. The second to fourth amplifiers are configured to be selectively driven based on the power level of the input signal. The impedances of the amplifiers in operation can be changed depending on which of the second to fourth amplifiers are driven. This configuration enables multiple back-off levels to be set. This thereby ensures that a back-off level of 6 dB or higher can be achieved in the power amplifier circuit.

### BRIEF DESCRIPTION OF THE SEVERAL VIEWS OF THE DRAWINGS

FIG. 1 schematically illustrates the configuration of a communication device including a power amplifier circuit according to a first embodiment.

FIG. 2 illustrates the detailed configuration of a transmit circuit and a power supply circuit in FIG. 1.

Each of FIGS. 3A, 3B and 3C illustrates envelope tracking modes in the power supply circuit.

FIG. 4 schematically illustrates the operation of a Doherty amplifier.

FIG. 5 illustrates the impedance in the power amplifier circuit in a first operating state.

FIG. 6 illustrates the impedance in the power amplifier circuit in a second operating state.

FIG. 7 illustrates the impedance in the power amplifier circuit in a third operating state.

FIG. 8 illustrates the relationship between the output power and the efficiency of the power amplifier circuit in FIG. 1.

FIG. 9 illustrates a partial circuit diagram of a power amplifier circuit according to a second embodiment.

FIG. 10 illustrates a partial circuit diagram of a power amplifier circuit according to a third embodiment.

FIG. 11 illustrates a partial circuit diagram of a power amplifier circuit according to a fourth embodiment.

### DETAILED DESCRIPTION OF THE DISCLOSURE

Hereinafter, embodiments of the present disclosure will be described in detail with reference to the drawings. In the drawings, identical or equivalent parts are denoted by the same reference numerals, and descriptions thereof are omitted.

### First Embodiment

### (Configuration of Communication Device)

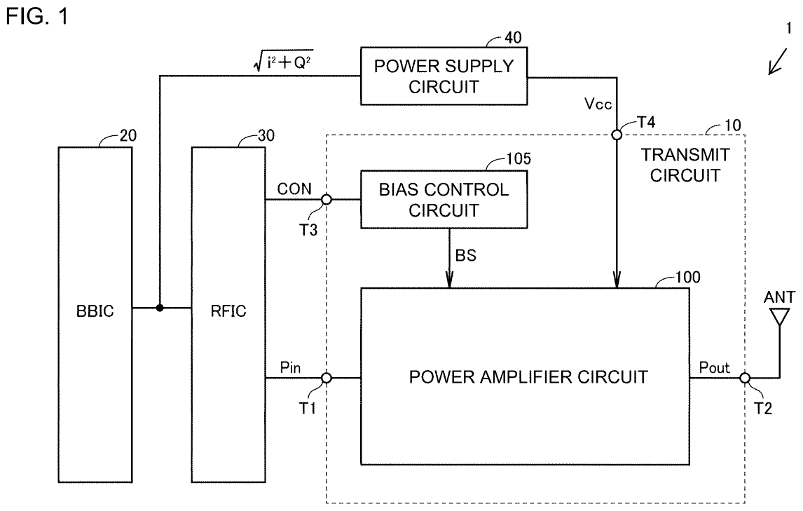

FIG. 1 schematically illustrates the configuration of a communication device 1 including a power amplifier circuit 100 according to a first embodiment. Examples of the communication device 1 include mobile terminals, such as mobile phones, smartphones, and tablet computers, and personal computers having communication functionality.

Referring to FIG. 1, the communication device 1 includes an antenna ANT, a transmit circuit 10, a baseband integrated circuit (BBIC) 20 that constitutes a baseband signal processing circuit, a radio frequency integrated circuit (RFIC) 30, and a power supply circuit 40. The transmit circuit 10 includes input terminals T1, T3, and T4, an output terminal T2, the power amplifier circuit 100, and a bias control circuit 105. The communication device 1 generally upconverts intermediate-frequency (IF) signals delivered from the BBIC 20 into radio-frequency (RF) signals by the RFIC 30, amplifies the radio-frequency signals by the power amplifier circuit 100, and emits the radio-frequency signals from the antenna ANT.

The RFIC 30 is an example of a signal processing circuit for processing radio-frequency signals. The RFIC 30 upconverts intermediate-frequency signals delivered from the BBIC 20 to radio-frequency signals and outputs the generated radio-frequency signals to the transmit circuit 10 through the input terminal T1.

The RFIC 30 generates, based on transmission information from the BBIC 20, a control signal CON for controlling the power amplifier circuit 100. The generated control signal CON is outputted to the bias control circuit 105 through the input terminal T3.

The bias control circuit 105 generates, based on the control signal CON, a bias signal BS for controlling the magnitude and supply timing of the bias current for amplifiers included in the power amplifier circuit 100 and outputs the bias signal BS to the power amplifier circuit 100.

The power supply circuit 40 generates, based on the transmission information from the BBIC 20, a supply voltage Vcc to be supplied to the power amplifier circuit 100. The generated supply voltage Vcc is supplied to the power amplifier circuit 100 through the input terminal T4.

The power amplifier circuit 100 amplifies an input signal Pin received from the RFIC 30 through the input terminal T1 to generate an output signal Pout.

The antenna ANT is coupled to the output terminal T2 of the transmit circuit 10. The antenna ANT emits, as radio waves, the output signal Pout that is a radio-frequency signal outputted from the transmit circuit 10.

### (Detailed Configuration of Power Converter Circuit)

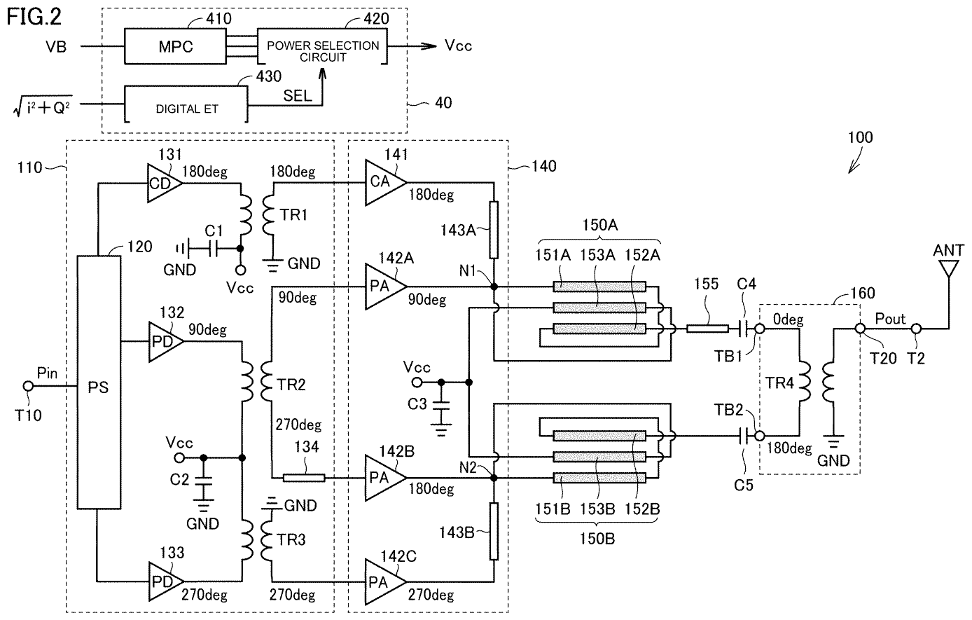

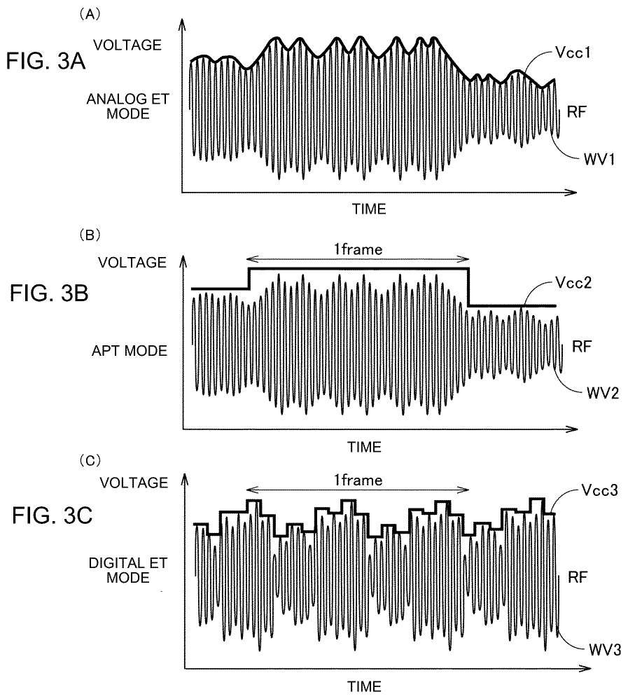

The following describes, with reference to FIG. 2, the detailed configuration of the power amplifier circuit 100 and the power supply circuit 40 in the transmit circuit 10.

The power supply circuit 40 is an example of a digital tracker, and is configured to supply the supply voltage Vcc having multiple different voltage levels to the power amplifier circuit 100. The power supply circuit 40 includes a multilevel power converter (MPC) 410, a power selection circuit 420, and a digital envelope tracker (digital ET) 430.

The MPC 410 includes multiple DC-DC converters, which are not illustrated in FIG. 2. The MPC 410 converts a battery voltage VB supplied from an external battery to multiple different voltage levels and supplies the voltages to the power selection circuit 420.

The digital ET 430 receives, from the BBIC 20, I and Q waveform signals of the transmit signal and tracks the envelope of the transmit signal in a digital ET mode. The digital ET 430 generates a selection signal SEL corresponding to the voltage level of the envelope of the transmit signal and outputs the selection signal SEL to the power selection circuit 420.

The power selection circuit 420 selects a voltage corresponding to the selection signal SEL from the multiple voltage levels supplied from the MPC 410 and supplies the voltage as the supply voltage Vcc to the power amplifier circuit 100.

The power amplifier circuit 100 includes an input terminal T10, an output terminal T20, a splitter 110, a power amplifier stage 140, transmission-line transformers (TLT: Transmission Line Trance) 150A and 150B, a phase shifter 155, and a converter circuit 160. The power amplifier stage 140 includes a carrier amplifier 141 and peaking amplifiers 142A, 142B, and 142C.

The power amplifier circuit 100 is supplied with the input signal Pin from the RFIC 30 at the input terminal T10, amplifies the input signal Pin, and outputs the output signal Pout from the output terminal T20 to the antenna ANT.

The bias control circuit 105 includes a phase shifter circuit (PS) 120, preamplifiers 131, 132, and 133 configured to drive the respective amplifiers in the power amplifier stage 140, transformers TR1, TR2, and TR3, and a phase shifter 134.

The phase shifter circuit 120 converts the phase of the input signal Pin supplied through the input terminal T10 and splits the input signal Pin among three paths. More specifically, the phase shifter circuit 120 supplies the input signal Pin having a phase advance of 180° relative to a reference to a first path coupled to the preamplifier 131. The phase shifter circuit 120 supplies the input signal Pin having a phase advance of 90° relative to the reference to a second path coupled to the preamplifier 132. The phase shifter circuit 120 supplies the input signal Pin having a phase advance of 270° relative to the reference to a third path coupled to the preamplifier 133. The preamplifiers 131, 132, and 133 amplify the split input signal Pin with predetermined gains and respectively deliver amplified signals to the transformers TR1, TR2, and TR3.

The preamplifier 131 is an amplifier configured to drive the carrier amplifier 141. The preamplifier 132 is an amplifier configured to drive the peaking amplifiers 142A and 142B. The preamplifier 133 is an amplifier configured to drive the peaking amplifier 142C.

The output terminal of the preamplifier 131 is coupled to one end of the primary winding of the transformer TR1. The other end of the primary winding of the transformer TR1 is supplied with the supply voltage Vcc. A capacitor C1 is coupled between a supply terminal for the supply voltage Vcc of the transformer TR1 and a ground potential GND. The capacitor C1 is a bypass capacitor and is configured to suppress voltage fluctuations in the supply voltage Vcc.

One end of the secondary winding of the transformer TR1 is coupled to the carrier amplifier 141. The other end of the secondary winding of the transformer TR1 is coupled to a ground potential GND. The carrier amplifier 141 is supplied with a signal that is in phase with the signal outputted from the preamplifier 131.

The output terminal of the preamplifier 132 is coupled to one end of the primary winding of the transformer TR2. The other end of the primary winding of the transformer TR2 is supplied with the supply voltage Vcc. A capacitor C2, which is a bypass capacitor, is coupled between a supply terminal for the supply voltage Vcc of the transformer TR2 and a ground potential GND.

One end of the secondary winding of the transformer TR2 is coupled to the peaking amplifier 142A. The other end of the secondary winding of the transformer TR2 is coupled to the peaking amplifier 142B via the phase shifter 134. The phase shifter 134 is, for example, a quarter-wavelength line and is configured to introduce a phase delay of 90° to the signal delivered to the other end of the secondary winding of the transformer TR2. With this configuration, the peaking amplifier 142B is supplied with a signal that is in phase with the signal outputted from the preamplifier 132, while the peaking amplifier 142C is supplied with a signal having a phase advance of 90° relative to the signal outputted from the preamplifier 132.

The output terminal of the preamplifier 133 is coupled to one end of the primary winding of the transformer TR3. The other end of the primary winding of the transformer TR3 is supplied with the supply voltage Vcc. In the circuit illustrated in FIG. 2, the other end of the primary winding of the transformer TR3 is coupled to the other end of the primary winding of the transformer TR2.

One end of the secondary winding of the transformer TR3 is coupled to the peaking amplifier 142C. The other end of the secondary winding of the transformer TR3 is coupled to a ground potential GND. The peaking amplifier 142C is supplied with a signal that is in phase with the signal outputted from the preamplifier 133.

With the splitter 110 configured as described above, the carrier amplifier 141 and the peaking amplifier 142B are supplied with signals having a phase advance of 90° relative to the signal supplied to the peaking amplifier 142A. The peaking amplifier 142C is supplied with a signal having a phase advance of 180° relative to the signal supplied to the peaking amplifier 142A.

The power amplifier stage 140 further includes phase shifters 143A and 143B, in addition to the carrier amplifier 141 and the peaking amplifiers 142A, 142B, and 142C.

The output terminal of the carrier amplifier 141 is coupled to the output terminal of the peaking amplifier 142A via the phase shifter 143A. The output terminal of the peaking amplifier 142C is coupled to the output terminal of the peaking amplifier 142B via the phase shifter 143B. The carrier amplifier 141 and the peaking amplifiers 142A to 143C individually amplify the input radio-frequency signals at predetermined gains and output the signals.

The phase shifters 143A and 143B are, for example, quarter-wavelength lines and are configured to introduce a phase delay of 90° to the signals amplified by the carrier amplifier 141 and the peaking amplifier 142C. As a result, the signal outputted from the carrier amplifier 141 and the signal outputted from the peaking amplifier 142A are combined in phase at a connection node N1 between the peaking amplifier 142A and the phase shifter 143A. Similarly, the signal outputted from the peaking amplifier 142B and the signal outputted from the peaking amplifier 142C are combined in phase at a connection node N2 between the peaking amplifier 142B and the phase shifter 143B.

The phase shifters 143A and 143B are also configured to rotate the load impedance by 180° on the Smith chart. This means that the phase shifters 143A and 143B also operate as impedance inverters.

As used in this specification, “connection node” does not refer to a specific point on a path; different locations on the circuit are treated as “connection nodes” when the locations are electrically identical (at the same potential). For example, in FIG. 2, any locations on the line connecting the output end of the peaking amplifier 142A and the phase shifter 143A correspond to the “connection node N1,” regardless of whether the locations are different from the point labeled “N1” in the circuit.

The power amplifier stage 140, as a whole, functions as a Doherty amplifier. In the Doherty amplifier, the carrier amplifier 141 is driven at all times, and the peaking amplifiers 142A, 142B, and 142C sequentially start to be driven as the input-signal voltage level increases. A class-A or class-AB amplifier with relatively low distortion is used as the carrier amplifier 141. Conversely, class-C amplifiers are used as the peaking amplifiers 142A, 142B, and 142C. By using class-C amplifiers, the peaking amplifiers 142A, 142B, and 142C stop amplification when the input-signal voltage level decreases to a predetermined level or lower.

The TLT 150A is coupled to the connection node N1 between the phase shifter 143A and the peaking amplifier 142A, that is, the output end of the peaking amplifier 142A. The TLT 150B is coupled to the connection node N2 between the phase shifter 143B and the peaking amplifier 142B, that is, the output end of the peaking amplifier 142B.

The TLTs 150A and 150B are impedance transformers, each consisting of three parallel lines with line lengths ranging from ⅛ wavelength to ¼ wavelength.

The TLT 150A includes a first line 151A, a second line 152A, and a third line 153A. One end of the first line 151A is coupled to the connection node N1 of the power amplifier stage 140. The other end of the first line 151A is coupled to one end of the second line 152A.

The other end of the second line 152A is coupled to a balanced terminal TB1 (first balanced terminal) of the converter circuit 160 via the phase shifter 155 and a capacitor C4. The capacitor C4 removes the direct-current component from the signal that has passed through the TLT 150A. The phase shifter 155 is, for example, a quarter-wavelength line and is configured to introduce a phase delay of 90° to the radio-frequency signal that has passed through the TLT 150A.

One end of the third line 153A is supplied with the supply voltage Vcc, and the other end of the third line 153A is coupled to the connection node N1. The supply voltage Vcc is used as the drive power for the carrier amplifier 141 and the peaking amplifier 142A through the third line 153A. A capacitor C3 is coupled between a supply terminal for the supply voltage Vcc and a ground potential GND. The capacitor C3 is a bypass capacitor and is configured to suppress voltage fluctuations in the supply voltage Vcc.

The first line 151A, the second line 152A, and the third line 153A are arranged in parallel to ensure that the currents flow in the same direction. The third line 153A is positioned to provide coupling with the first line 151A and the second line 152A. This configuration of the three lines enables the TLT 150A to operate as an impedance transformer.

Similarly, the TLT 150B includes a first line 151B, a second line 152B, and a third line 153B. One end of the first line 151B is coupled to the connection node N2 of the power amplifier stage 140. The other end of the first line 151B is coupled to one end of the second line 152B. The other end of the second line 152B is coupled to a balanced terminal TB2 (second balanced terminal) of the converter circuit 160 via a capacitor C5. The capacitor C5 removes the direct-current component from the signal that has passed through the TLT 150B.

One end of the third line 153B is supplied with the supply voltage Vcc, and the other end of the third line 153B is coupled to the connection node N2. The supply voltage Vcc is supplied as the drive power for the peaking amplifier 142B and peaking amplifier 142C through the third line 153B. In the example of the power amplifier circuit 100 in FIG. 2, the third line 153A of the TLT 150A and the third line 153B of the TLT 150B are coupled to a common power supply terminal.

The first line 151B, the second line 152B, and the third line 153B are arranged in parallel to ensure that the currents flow in the same direction. The third line 153B is positioned to provide coupling with the first line 151B and the second line 152B. This configuration of the three lines enables the TLT 150B to operate as an impedance transformer.

The converter circuit 160 is configured to convert balanced lines into an unbalanced line. The converter circuit 160 includes a magnetically coupled transformer (MCT: Magnetic Coupled Transformer) TR4. One end of the primary winding of the magnetically coupled transformer TR4 is coupled to the balanced terminal TB1, and the other end is coupled to the balanced terminal TB2. One end of the secondary winding of the magnetically coupled transformer TR4 is coupled to the antenna ANT via the output terminal T20, and the other end of the secondary winding is coupled to a ground potential GND.

As described above, the phase of the signal outputted from the peaking amplifier 142B leads the phase of the signal outputted from the peaking amplifier 142A by 90°. Accordingly, the phase of the signal that has passed through the TLT 150B also leads the phase of the signal that has passed through the TLT 150A by 90°. The phase of the signal that has passed through the TLT 150A is delayed by 90° by the phase shifter 155. As a result, the signal inputted to the balanced terminal TB1 becomes antiphase with the signal inputted to the balanced terminal TB2. As a result, the output signal Pout, which is outputted through the output terminal T20 from the magnetically coupled transformer TR4, is obtained by combining the signal from the TLT 150A and the signal from the TLT 150B in phase.

In the power amplifier circuit 100 of the first embodiment, a Doherty amplifier is implemented by a combination of the carrier amplifier 141 and the peaking amplifier 142A, and another Doherty amplifier is implemented by a combination of the peaking amplifier 142B and the peaking amplifier 142C. Furthermore, another Doherty amplifier is implemented by the carrier amplifier 141 when the peaking amplifier 142A is not driven in the two Doherty amplifiers, the peaking amplifier 142C when the peaking amplifier 142B is not driven in the two Doherty amplifiers, and the phase shifter 155. Overall, the power amplifier circuit 100 can be regarded as a two-stage Doherty amplifier.

As described above, in the power amplifier circuit 100 of the first embodiment, a two-stage Doherty amplifier can be implemented by selectively driving, based on the power level of the input signal Pin, the peaking amplifiers 142A to 143C as needed. This configuration enables highly efficient signal amplification.

### (Approach to Increasing Back-Off Level)

For wireless communication devices, new communication standards such as 6G are being developed to achieve higher capacity and faster communications. These new communication standards may employ signals in higher frequency bands than earlier standards. In general, signals in higher frequency bands tend to be attenuated more easily than signals in lower frequency bands. For this reason, further improvement in the efficiency of power amplifier circuits is required. Furthermore, the usable frequency band width is being expanded. To satisfy these requirements, methods for controlling power amplifier circuits that are different from known methods are needed.

### (1) Tracking Mode

Some tracking modes for signals to be transmitted are known for adjusting the supply voltage level of power amplifiers. In general, tracking modes are broadly classified into envelope tracking mode and average power tracking (APT) mode. Envelope tracking mode is further classified into “digital envelope tracking mode (digital ET mode)” and “analog envelope tracking mode (analog ET mode).” In the envelope tracking mode, the supply voltage level is set based on an envelope signal that represents the envelope of the input signal. In the APT mode, the supply voltage level is set based on the average output power over a given period, rather than on an envelope signal.

Each of FIGS. 3A, 3B and 3C illustrates an overview of these tracking modes. FIG. 3A provides a graph illustrating an example of the supply voltage transition in the analog ET mode. FIGS. 3B and 3C provide graphs respectively illustrating examples of the supply voltage transition in the APT mode and the digital ET mode. In each graph, the horizontal axis indicates time and the vertical axis indicates voltage. The thick solid lines Vcc1 to Vcc3 illustrate the supply voltages in the respective modes, and the thin solid lines WV1 to WV3 illustrate the output signal Pout, which is a modulated radio-frequency signal.

In the analog ET mode (upper part (A)), the supply voltage is set to vary continuously to follow the envelope of the input signal Pin. The supply voltage waveform in the analog ET mode is an analog waveform rather than a digital waveform.

The analog ET mode is the most efficient tracking because the supply voltage always corresponds to the amplitude variation of the input signal Pin. However, because the supply voltage needs to be varied continuously, the supply voltage cannot follow the envelope of the modulated radio-frequency signal when the amplitude variation of the input signal is relatively large or when the modulation band width is relatively wide.

Next, in the APT mode in FIG. 3B, the supply voltage is set at different voltage levels for each given single-frame units. The supply voltage has a digital waveform and forms a square wave. As used herein, frame means a unit that constitutes a modulated radio-frequency signal. For example, the frame length is 10 ms.

Specifically, in the APT mode, the voltage level of the supply voltage is determined based on the average output power rather than the envelope signal. In this case, it is unnecessary to rapidly change the supply voltage following the input signal Pin. However, since the voltage is set to correspond to the peak voltage of the input signal Pin over each frame, there is room for improvement in terms of power saving and efficiency.

In the digital ET mode (FIG. 3C), supply voltages with multiple discrete different voltage levels are set within a single frame. The supply voltage has a digital waveform and forms a square wave. Specifically, in the digital ET mode, a voltage level corresponding to the voltage of the input signal Pin in the target section of a frame is selected from among multiple different voltage levels based on the envelope signal. A voltage level is selected, based on the transmission information, to track the envelope of the modulated carrier wave. More specifically, a voltage level corresponding to the envelope value of each symbol is selected with reference to the ranges of envelope values associated with multiple different voltage levels.

When the input signal has high-frequency components and a wide modulation band width, the analog ET mode cannot make the supply voltage follow changes in the input signal, and thus the digital ET mode needs to be employed.

### (2) Doherty Amplifier

A Doherty amplifier is known as a configuration element that improves the amplification efficiency of power amplifier circuits. A Doherty amplifier has a basic configuration in which a carrier amplifier and a peaking amplifier are coupled in parallel between the input terminal and the output terminal, and in which a phase shifter that functions as an impedance inverter is provided between the carrier amplifier and a combining node. When the output power is relatively small, the carrier amplifier solely operates; when the output power is larger than a predetermined value, both the carrier and peaking amplifiers operate.

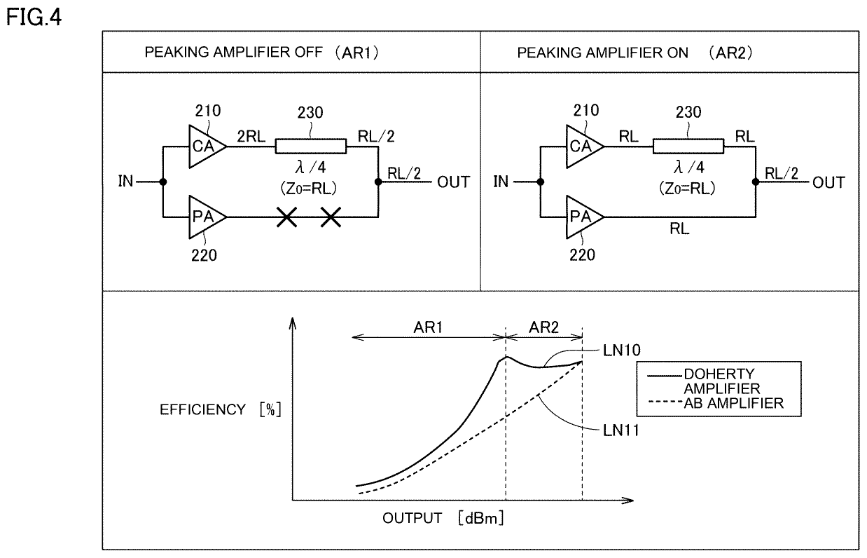

FIG. 4 schematically illustrates the operation of a Doherty amplifier. In FIG. 4, the upper part illustrates the circuit states and load impedances when a peaking amplifier 220 is in operation (right) and not in operation (left). The lower part illustrates the relationship between output power and efficiency for the Doherty amplifier in comparison with the relationship between output power and efficiency of a class-AB amplifier. In the lower part, the solid line LN10 illustrates the efficiency of the Doherty amplifier, and the dashed line LN11 illustrates the efficiency of the class-AB amplifier.

When both a carrier amplifier 210 and the peaking amplifier 220 are operating (right drawing in the upper part), the load impedance seen from each of the carrier amplifier 210 and the peaking amplifier 220 is RL, and the load impedance at the combining point (output terminal) is RL/2. By contrast, when the peaking amplifier 220 is turned off (left drawing in the upper part), the load impedance seen from the carrier amplifier 210 is 2RL due to a phase shifter 230 that functions as an impedance inverter.

Typically, amplifiers tend to increase in efficiency as the load impedance increases. For this reason, as illustrated in the graph in the lower part, the use of the Doherty amplifier increases the efficiency of the carrier amplifier 210 in the region AR1, in which the peaking amplifier 220 is turned off and the load impedance is increased, compared to the case of using the class-AB amplifier that can output the same peak power. In the region AR2, in which the peaking amplifier 220 is turned on, the parallel operation of the carrier amplifier 210 and the peaking amplifier 220 increases the efficiency.

In typical Doherty amplifier configurations, a back-off level of approximately 6 dB can be achieved. However, the required back-off level for power amplifier circuits can vary depending on, for example, the modulation scheme, the set voltage of the digital ET, and/or the target band width of the digital ET. Depending on the specifications required for the devices in which the power amplifier circuit is used, a back-off level greater than 6 dB may be necessary in certain cases.

To satisfy this demand, the power amplifier circuit of the first embodiment employs a Doherty amplifier composed of a single carrier amplifier and three peaking amplifiers, and changes the number of active peaking amplifiers based on the power level of the input signal. More specifically, a two-stage Doherty amplifier is implemented by selectively using the peaking amplifiers based on the power level of the input signal, as described in detail below, to achieve a back-off level of 12 dB.

### (Operation of Power Amplifier Circuit)

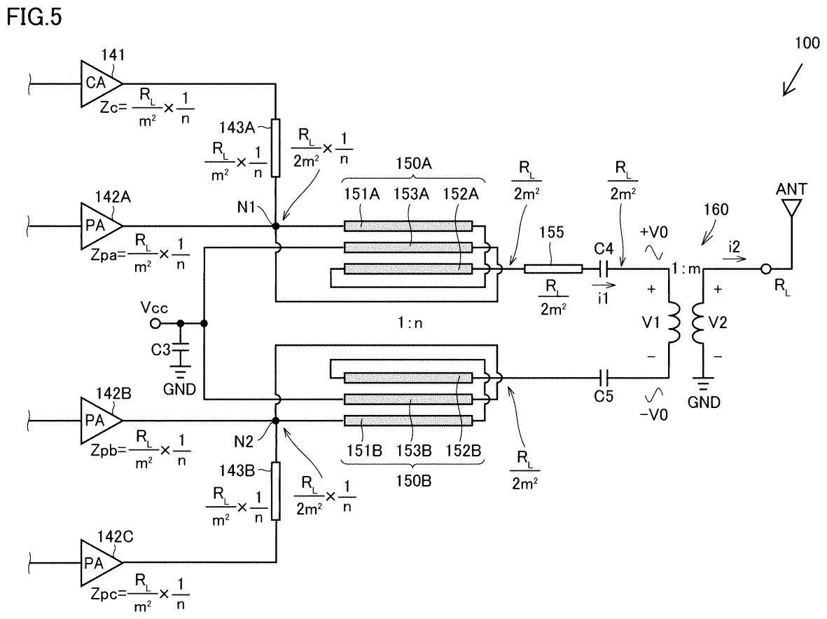

Next, the operation of the power amplifier circuit 100 will be described with reference to FIGS. 5 to 8. FIGS. 5 to 7 illustrate the impedances in the circuit of the power amplifier circuit 100 of the first embodiment in different operating states. The operating state changes with the supply voltage Vcc. In the example of the first embodiment, the supply voltage Vcc is switched among three levels, 5.2 V, 2.0 V, and 0.8 V, by the digital ET. The case of Vcc=5.2 V is defined as a first operating state, Vcc=2.0 V is defined as a second operating state, and Vcc=0.8 V is defined as a third operating state.

The first operating state (FIG. 5) corresponds to a state in which the power level of the input signal Pin is greater than a first power value. In the first operating state, since a relatively large amount of power is required, all of the peaking amplifiers 142A, 142B, and 142C are driven, and a total of four amplifiers, including the carrier amplifier 141, are used for amplification.

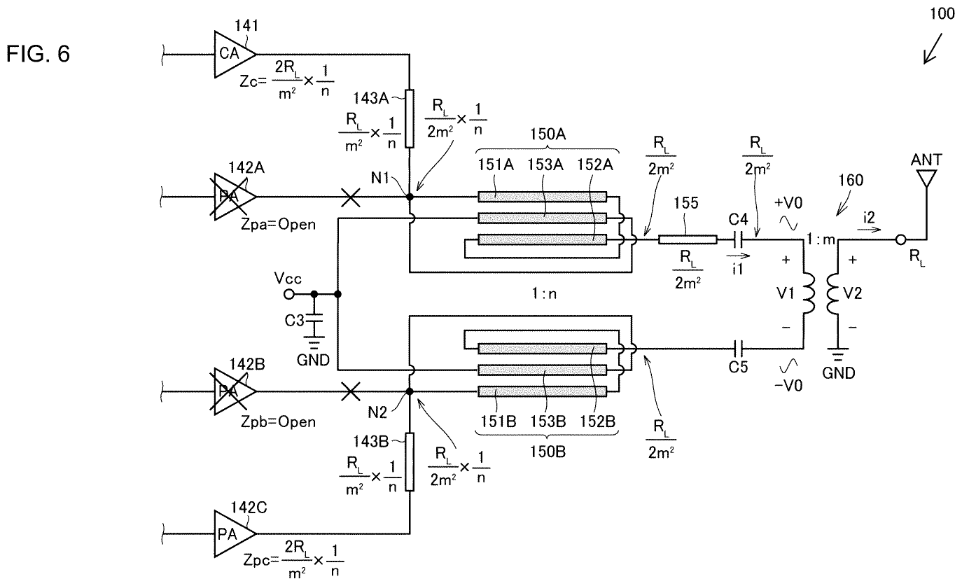

The second operating state (FIG. 6) corresponds to a state in which the power level of the input signal Pin is a second power value that is smaller than the first power value. In the second operating state, the peaking amplifiers 142A and 142B are not driven, while the peaking amplifier 142C is driven. This means that the carrier amplifier 141 and the peaking amplifier 142C are used for amplification.

The second operating state (FIG. 6) corresponds to a state in which the power level of the input signal Pin is a third power value that is still smaller than the second power value. In the second operating state, the peaking amplifiers 142A, 142B, and 142C are not driven, and the carrier amplifier 141 is solely used for amplification.

FIG. 5 illustrates the impedance in the power amplifier circuit 100 in the first operating state.

In the following description, the load impedance of the antenna ANT is denoted as R_{L}, the impedance conversion ratio of the TLTs 150A and 150B is 1:n, and the impedance conversion ratio of the converter circuit 160 is 1:m. In the converter circuit 160, the voltages of the signals supplied to the balanced terminals TB1 and TB2 are respectively denoted as V0 and −V0, and the voltage at the primary winding is denoted as V1 and the voltage at the secondary winding is denoted as V2. In the converter circuit 160, the current flowing in the primary winding is denoted as i1, and the current flowing in the secondary winding is denoted as i2.

Since V2=mV1=2mV0 and i2=i1/m, the load impedance R_{L} is given by the following expression (1) in terms of V0 and i1.

$${R}_{L} = V 2 / i 2 = 2 m V Θ / ( i 1 / m ) = 2 {m}^{2} V Θ / i 1 \qquad Expression ( 1 )$$

Since the load impedance seen at the input end of the converter circuit 160 is expressed as V0/i1, transforming Expression (1) yields R_{L}/2m².

Since the impedance of the phase shifter 155 is set to the impedance (R_{L}/2m²) in the first operating state, the impedance at the output ends of the TLTs 150A and 150B is R_{L}/2m². As a result, the load impedance seen at each input end of the TLTs 150A and 150B (that is, the connection nodes N1 and N2) is (R_{L}/2m²)×(1/n).

At the connection node N1, the output signal from the carrier amplifier 141 and the output signal from the peaking amplifier 142A are combined. As a result, the load impedance Zc seen at the output end of the carrier amplifier 141 and the load impedance Zpa seen at the output end of the peaking amplifier 142A are each (R_{L}/m²)×(1/n).

Similarly, the load impedance Zpb seen at the output end of the peaking amplifier 142B, and the load impedance Zpc seen at the output end of the peaking amplifier 142C are each (R_{L}/m²)×(1/n). The impedances of the phase shifters 143A and 143B are each set to (R_{L}/m²)×(1/n).

FIG. 6 illustrates the impedance in the power amplifier circuit 100 in the second operating state. In the second operating state, the peaking amplifiers 142A and 142B are not driven. The load impedance Zpa seen at the output end of the peaking amplifier 142A and the load impedance Zpb seen at the output end of the peaking amplifier 142B are thus both open.

The impedances of the phase shifters 143A and 143B are set to (R_{L}/m²)×(1/n). As a result, the load impedance Zc seen at the output end of the carrier amplifier 141 and the load impedance Zpc seen at the output end of the peaking amplifier 142C are each (2R_{L}/m²)×(1/n). This means that in the second operating state, the load impedance seen at the output ends of the driven amplifiers becomes twice the impedance in the first operating state.

In the second operating state, the number of amplifiers is halved and the load impedance is doubled in each of the Doherty amplifier composed of the carrier amplifier 141 and the peaking amplifier 142A, and the Doherty amplifier composed of the peaking amplifier 142B and the peaking amplifier 142C. As a result, a back-off level of 6 dB is achieved in the first operating state and in the second operating state.

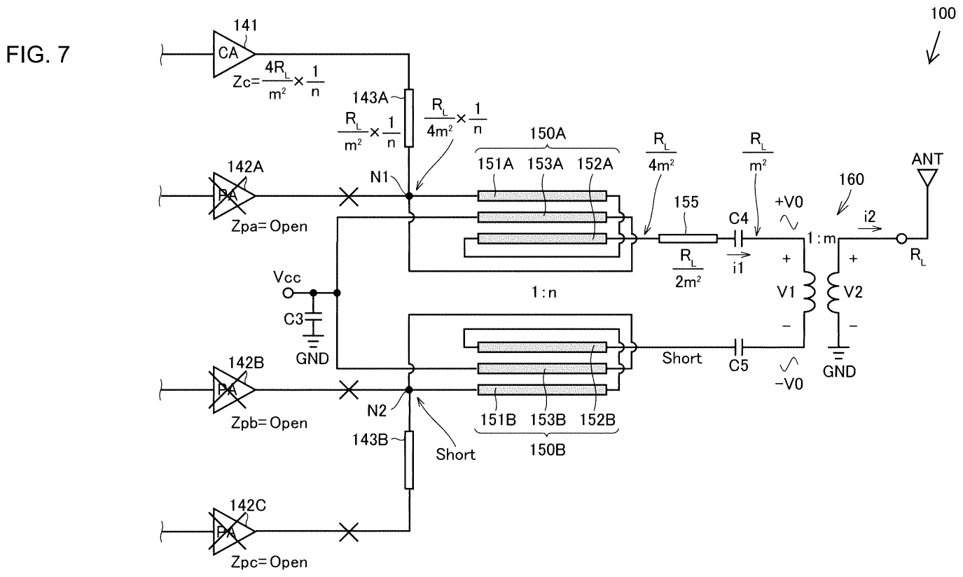

FIG. 7 illustrates the impedance in the power amplifier circuit 100 in the third operating state. In the third operating state, the peaking amplifiers 142A, 142B, and 142C are not driven. The load impedance Zpa seen at the output end of the peaking amplifier 142A, the load impedance Zpb seen at the output end of the peaking amplifier 142B, and the load impedance Zpc seen at the output end of the peaking amplifier 142C are thus open.

At the connection node N2, a short-circuited state is generated by the phase shifter 143B. As a result, the impedance at the balanced terminal TB2 of the converter circuit 160 is short-circuited, and the load impedance seen at the balanced terminal TB1 becomes R_{L}/m².

Since the impedance of the phase shifter 155 is set to R_{L}/2m², the load impedance at the output end of the TLT 150A is R_{L}/4m², and the load impedance at the connection node N1 is (R_{L}/4m²)/(1/n). Thus, the load impedance Zc seen at the output end of the carrier amplifier 141 is (4R_{L}/m²)/(1/n). This means that in the third operating state, the load impedance Zc seen at the output end of the carrier amplifier 141 is four times the impedance in the first operating state and twice the impedance in the second operating state.

In the third operating state, the number of amplifiers is halved and the load impedance is doubled in the Doherty circuit composed of the carrier amplifier 141, the peaking amplifier 142C, and the phase shifter 155. As a result, a back-off level of 6 dB is achieved in the second operating state and in the third operating state.

As described above, in the power amplifier circuit 100, a back-off level of 6 dB can be achieved by the Doherty amplifier composed of the carrier amplifier 141 and the peaking amplifier 142A, as well as by the Doherty amplifier composed of the peaking amplifier 142B and the peaking amplifier 142C. In addition, a back-off level of 6 dB can be achieved by the Doherty amplifier composed of the carrier amplifier 141 and the peaking amplifier 142C. As a result, the power amplifier circuit 100 achieves a total back-off level of 12 dB.

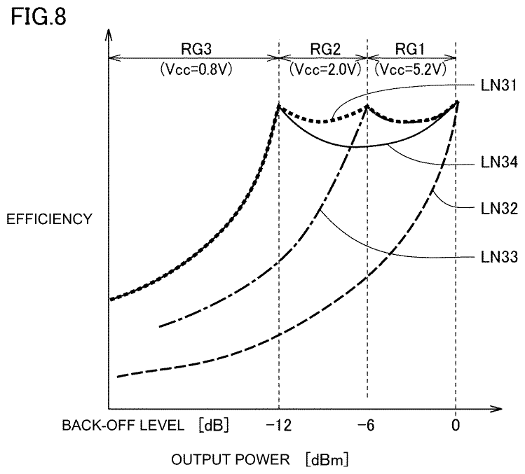

FIG. 8 illustrates the relationship between the output power and the efficiency of the power amplifier circuit 100. In FIG. 8, the horizontal axis represents the power level of the output signal Pout from the output terminal T20 to the antenna ANT, and the vertical axis represents the efficiency of the power amplifier circuit 100.

In FIG. 8, the dashed line LN32 illustrates the graph obtained when four class-AB amplifiers, namely the carrier amplifier 141 and the peaking amplifiers 142A, 142B, and 142C, are driven in the APT mode. The dot-dash line LN33 illustrates the graph obtained when the operating state is switched between the state in which the carrier amplifier 141 and the peaking amplifier 142C are driven and the peaking amplifiers 142A and 142B are not driven (that is, the second operating state) and the first operating state. The solid line LN34 illustrates the graph obtained when the operating state is switched between the state in which the carrier amplifier 141 is solely driven and the peaking amplifiers 142A, 142B, and 142C are not driven (that is, the third operating state) and the first operating state. The dashed line LN31 illustrates the graph obtained when the operating state is switched among the first operating state, the second operating state, and the third operating state based on the power level of the output signal Pout, as in the first embodiment.

The region until the amplifiers are saturated in the third operating state is denoted as RG3. The region until the amplifiers are saturated in the second operating state is denoted as RG2. The region until the amplifiers are saturated in the first operating state is denoted as RG1. The supply voltage Vcc in the first operating state is set to 5.2 V. The supply voltage Vcc in the second operating state is set to 2.0 V. The supply voltage Vcc in the third operating state is set to 0.8 V.

When the power level of the input signal Pin decreases from the first power value to the second power value, as described with reference to FIG. 6, the Doherty amplifier composed of the carrier amplifier 141 and the peaking amplifier 142A and the Doherty amplifier composed of the peaking amplifiers 142B and 142C increase the impedances presented to the driven carrier amplifier 141 and the driven peaking amplifier 142C. As a result, the efficiency increases compared to the case in which the peaking amplifiers 142A and 142B are driven.

When the power level of the input signal Pin decreases from the second power value to the third power value, as described in FIG. 7, the Doherty amplifier composed of the carrier amplifier 141 and the peaking amplifier 142C further increases the driven carrier amplifier 141. As a result, the efficiency increases compared to the case in which the carrier amplifier 141 and the peaking amplifier 142C are driven.

As described above, when the power level of the input signal Pin increases from a lower level to a higher level, the supply voltage Vcc is changed based on the power level, and the number of active peaking amplifiers is also changed. This configuration improves the efficiency of the power amplifier circuit 100 in the low-power region. Selectively driving or not driving the peaking amplifiers in stages increases the back-off level beyond 6 dB, that is, the power difference between the output power when the peaking amplifiers 142A, 142B, and 142C are driven (first operating state) and the output power when the peaking amplifiers 142A, 142B, and 142C are not driven (third operating state).

The “carrier amplifier 141,” the “peaking amplifier 142A,” the “peaking amplifier 142B,” and the “peaking amplifier 142C” in the first embodiment respectively correspond to a “first amplifier” to a “fourth amplifier” in the present disclosure. The “phase shifter 143A,” the “phase shifter 143B,” and the “phase shifter 155” in the first embodiment respectively correspond to a “first phase shifter” to a “third phase shifter” in the present disclosure. The “TLT 150A” and the “TLT 150B” in the first embodiment respectively correspond to a “first transmission-line transformer” and a “second transmission-line transformer” in the present disclosure. The “first line 151A” to the “third line 153A” in the TLT 150A of the first embodiment respectively correspond to a “fourth line” to a “sixth line” in the present disclosure. The “first line 151B” to the “third line 153B” in the TLT 150B of the first embodiment respectively correspond to a “seventh line” to a “ninth line” in the present disclosure. The “bias control circuit 105” in the present disclosure corresponds to a “control circuit” in the present disclosure.

### Second Embodiment

In a second embodiment, another configuration of the converter circuit will be described.

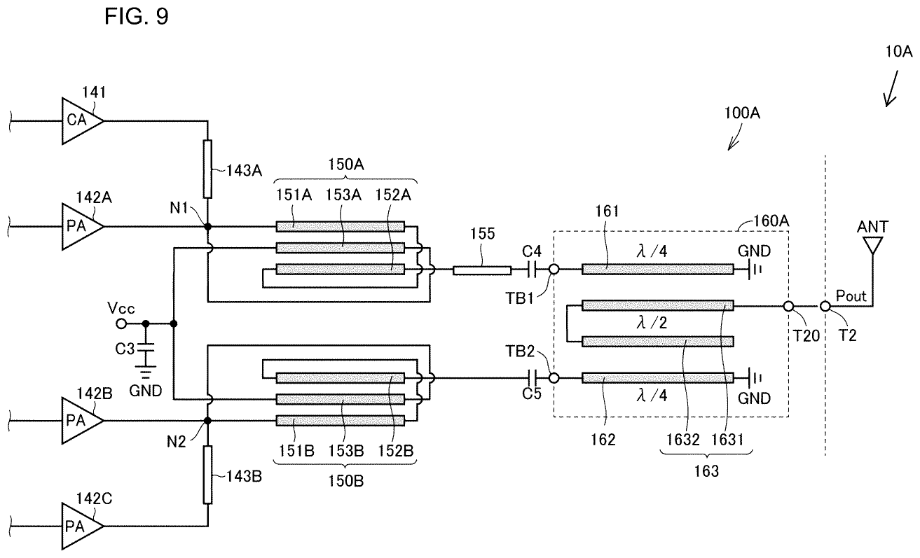

FIG. 9 illustrates a partial circuit diagram of a transmit circuit 10A according to the second embodiment. FIG. 6 illustrates the circuit located after the power amplifier stage 140 of a power amplifier circuit 100A in the transmit circuit 10A. The power amplifier circuit 100A is configured by replacing the converter circuit 160 in the power amplifier circuit 100 in FIG. 1 with a converter circuit 160A.

The converter circuit 160A is a Marchand balun. The converter circuit 160A is composed of lines 161 and 162 having a length of λ/4 and a line 163 having a length of λ/2.

One end of the line 161 is coupled to the output terminal of the TLT 150A via the capacitor C4 and the phase shifter 155, and the other end of the line 161 is coupled to a ground potential GND. Similarly, one end of the line 162 is coupled to the output terminal of the TLT 150B via the capacitor C5, and the other end of the line 162 is coupled to a ground potential GND.

The line 163 includes line sections 1631 and 1632, one ends of which are coupled to each other. The other end of the line section 1631 is coupled to the antenna ANT via the output terminal T20. The other end of the line section 1632 is an open end. The line section 1631 and the line 161 can provide coupling, and the line section 1632 and the line 162 can provide coupling.

The lines are arranged such that the current in the lines 161 and 162 flows in the opposite direction to the current flowing in the line 163. As a result, the radio-frequency signals from the TLTs 150A and 150B, which differ in phase by 180°, are combined and outputted from the line 163.

When a Marchand balun is used as a converter circuit from balanced lines to an unbalanced line, a relatively large substrate area is required for forming the lines. However, the insertion loss is lower than in the case in which an MCT is used as in the power amplifier circuit 100. This configuration thus further improves the circuit efficiency of the power amplifier circuit.

The “lines 161” to the “line 163” in the second embodiment respectively correspond to a “first line” to a “third line” in the present disclosure.

### Third Embodiment

In a third embodiment, a radio-frequency termination circuit for removing harmonics of radio-frequency signals is described.

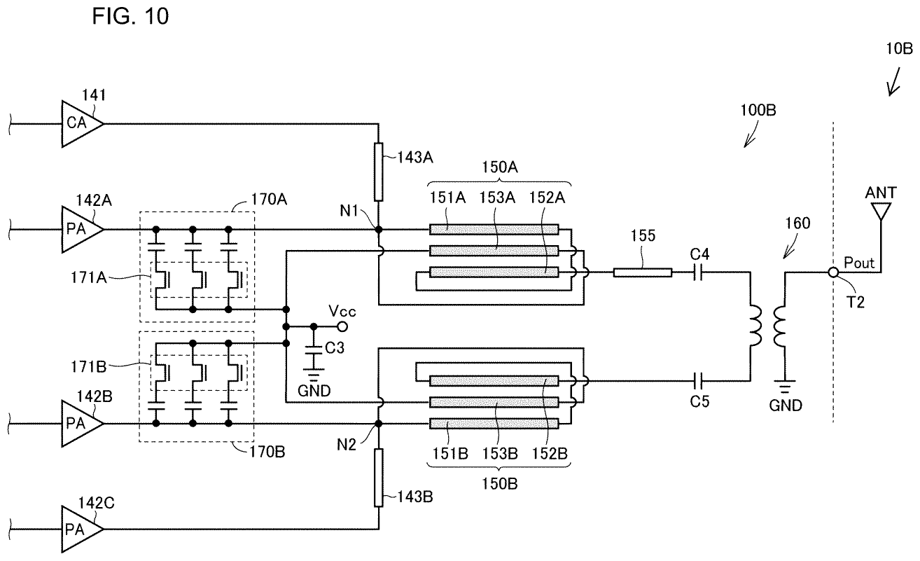

FIG. 10 illustrates a partial circuit diagram of a transmit circuit 10B according to the third embodiment. A power amplifier circuit 100B of the transmit circuit 10B is configured, in addition to the configuration of the power amplifier circuit 100 illustrated in FIG. 1, by adding a capacitor circuit 170A between the third line 153A of the TLT 150A and the output terminal of the peaking amplifier 142A, and a capacitor circuit 170B between the third line 153B of the TLT 150B and the output terminal of the peaking amplifier 142B.

Each of the capacitor circuits 170A and 170B includes at least one capacitor and a switching circuit configured to switch the capacitor. In the example of the power amplifier circuit 100B, each of the capacitor circuits 170A and 170B is composed of three capacitors and three switching elements, each provided for a respective capacitor.

In the capacitor circuit 170A, the combinations of series-coupled capacitors and switching elements are coupled in parallel between the third line 153A of the TLT 150A and the output terminal of the peaking amplifier 142A. In the capacitor circuit 170B, the combinations of series-coupled capacitors and switching elements are coupled in parallel between the third line 153B of the TLT 150B and the output terminal of the peaking amplifier 142B.

The switching elements included in the capacitor circuit 170A are collectively referred to as the switching circuit 171A. The switching elements included in the capacitor circuit 170B are collectively referred to as the switching circuit 171B.

In each capacitor circuit, when any one of the switching elements is made conductive, an LC parallel resonant circuit is formed by the capacitor coupled to the switching element and the third line of the corresponding TLT.

Typically, an LC parallel resonant circuit has the characteristic that, as the frequency increases, the circuit becomes more capacitive, and thus the admittance increases in the frequency range above the resonant frequency. By appropriately setting the resonant frequency of the LC parallel resonant circuit, the output impedance of the corresponding peaking amplifier can present a short circuit in the second and third harmonic bands of the radio-frequency signal to be transmitted. As a result, the attenuation in these harmonic bands can be ensured. This configuration improves the circuit efficiency by preventing leakage of radio-frequency signals in the target frequency band to the power supply line, and also suppresses harmonics of radio-frequency signals.

When power is supplied to each amplifier in the power amplifier stage 140 through the TLTs, the line lengths of the TLTs are not necessarily be set to ¼ wavelength. In this case, the power supply line does not necessarily present an open circuit when viewed from the output end of the amplifier. In this case as well, forming an LC parallel resonant circuit by the capacitor included in the capacitor circuit and the third line of the TLT enables the power supply line to present an open circuit at the fundamental wave of the radio-frequency signal to be transmitted.

Each capacitor circuit does not need to include multiple capacitors. However, for example, in the case of a dual-band transmit circuit that selectively transmits signals in multiple frequency bands, providing capacitors corresponding to the frequency bands improves the characteristics across the multiple frequency bands.

The “capacitor circuit 170A” and the “capacitor circuit 170B” in the third embodiment respectively correspond to a “first capacitor circuit” and a “second capacitor circuit” in the present disclosure.

### Fourth Embodiment

In a fourth embodiment, a radio-frequency termination circuit for removing second harmonics of radio-frequency signals is described.

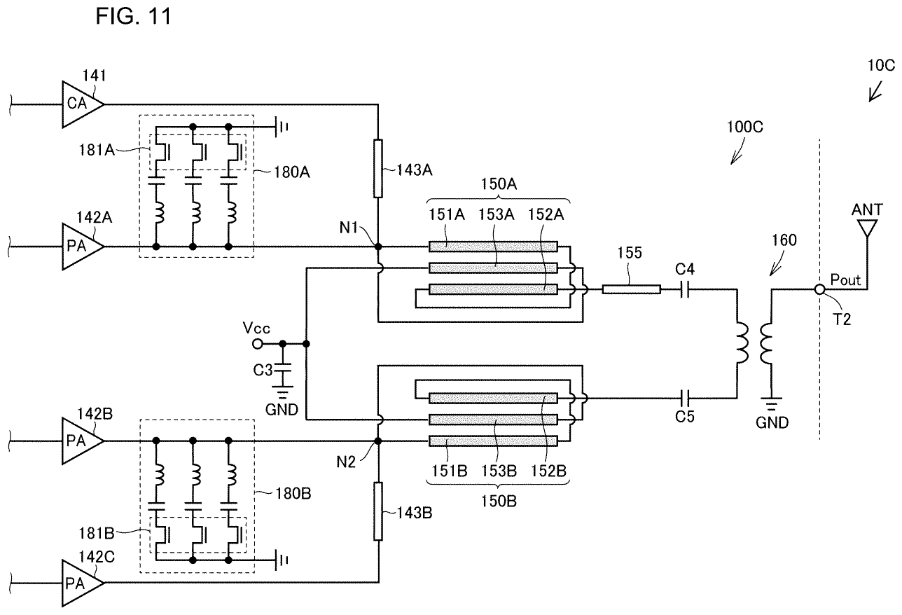

FIG. 11 illustrates a partial circuit diagram of a transmit circuit 10C according to the fourth embodiment. A power amplifier circuit 100C of the transmit circuit 10C is configured, in addition to the configuration of the power amplifier circuit 100 illustrated in FIG. 1, by adding resonator circuits 180A and 180B, each including at least one LC series resonant circuit, between the output terminals of the peaking amplifiers 142A and 142B and a ground potential GND.

The resonator circuits 180A and 180B respectively include switching circuits 181A and 181B configured to switch corresponding resonators, as well as at least one LC series resonant circuit. Each switching circuit includes a switching element coupled in series with at least one LC series resonant circuit. In the resonator circuits 180A and 180B, when any one of the switching elements is made conductive, the corresponding LC series resonant circuit operates as a band-stop filter. This configuration removes from the radio-frequency signal the components corresponding to the resonant frequency of the LC series resonant circuit.

Accordingly, the second harmonic component of the radio-frequency signal can be removed by setting the resonant frequency of the LC series resonant circuit to the frequency of the second harmonic of the radio-frequency signal to be transmitted.

The “resonator circuit 180A” and the “resonator circuit 180B” in the fourth embodiment respectively correspond to a “first resonator circuit” and a “second resonator circuit” in the present disclosure.

### Aspects

It will be understood by those skilled in the art that the exemplary embodiments described above are merely specific examples of the following aspects.

(Clause 1) A power amplifier circuit according to an aspect includes an input terminal, first to fourth amplifiers, first to third phase shifters, a converter circuit, and an output terminal. The first to fourth amplifiers are configured to amplify an input signal that is a radio-frequency signal received through the input terminal. The converter circuit is configured to convert a pair of balanced lines to an unbalanced line. The output terminal is coupled to the unbalanced line. The converter circuit includes a first balanced terminal and a second balanced terminal that are respectively coupled to corresponding ones of the pair of balanced lines. The first phase shifter is coupled between an output of the first amplifier and an output of the second amplifier. The second phase shifter is coupled between an output of the third amplifier and an output of the fourth amplifier. The third phase shifter is coupled between the output of the second amplifier and the first balanced terminal. The output of the third amplifier is coupled to the second balanced terminal. The second amplifier, the third amplifier, and the fourth amplifier are configured to be selectively driven based on a power level of the input signal.

(Clause 2) In the power amplifier circuit according to clause 1, when the power level of the input signal is within a first range, the first amplifier, the second amplifier, the third amplifier, and the fourth amplifier are driven. When the power level of the input signal is within a second range that is lower than the first range, the first amplifier and the fourth amplifier are driven, while the second amplifier and the third amplifier are not driven. When the power level of the input signal is within a third range that is lower than the second range, the first amplifier is driven, while the second amplifier, the third amplifier, and the fourth amplifier are not driven.

(Clause 3) The power amplifier circuit according to clause 2 further includes a splitter coupled to the input terminal, the splitter being configured to split the input signal received through the input terminal among the first amplifier, the second amplifier, the third amplifier, and the fourth amplifier with predetermined phase differences. Phases of signals inputted to the first amplifier and the third amplifier lead a phase of a signal inputted to the second amplifier by 90°. A phase of a signal inputted to the fourth amplifier leads the phase of the signal inputted to the second amplifier by 180°.

(Clause 4) In the power amplifier circuit according to any one of clauses 2 or 3, the converter circuit is a magnetically coupled transformer.

(Clause 5) In the power amplifier circuit according to any one of clauses 2 or 3, the converter circuit is a Marchand balun.

(Clause 6) In the power amplifier circuit according to clause 5, the Marchand balun includes a first line and a second line, and a third line configured to provide coupling with the first line and the second line. One end of the first line is coupled to the first balanced terminal, and another end of the first line is coupled to a ground potential. One end of the second line is coupled to the second balanced terminal, and another end of the second line is coupled to a ground potential. One end of the third line is coupled to the output terminal, and another end of the third line is an open end. When a wavelength of the radio-frequency signal is λ, the radio-frequency signal being a signal to be transmitted, each of the first line and the second line has a line length of λ/4, and the third line has a line length of λ/2.

(Clause 7) The power amplifier circuit according to any one of clauses 2 to 6 further includes a first transmission-line transformer coupled between the output of the second amplifier and the third phase shifter, and a second transmission-line transformer coupled between the output of the third amplifier and the second balanced terminal.

(Clause 8) In the power amplifier circuit according to clause 7, the first transmission-line transformer includes a fourth line and a fifth line that are coupled in series between the third phase shifter and the output of the second amplifier, and a sixth line configured to provide coupling with the fourth line and the fifth line. The second transmission-line transformer includes a seventh line and an eighth line that are coupled in series between the second balanced terminal and the output of the third amplifier, and a ninth line configured to provide coupling with the seventh line and the eighth line.

(Clause 9) In the power amplifier circuit according to clause 8, one end of the sixth line is coupled to the output of the second amplifier. One end of the ninth line is coupled to the output of the third amplifier. Another end of the sixth line and another end of the ninth line are configured to be supplied with a supply voltage. The power amplifier circuit further includes a first capacitor circuit and a second capacitor circuit. The first capacitor circuit is coupled between the other end of the sixth line and the output of the second amplifier. The second capacitor circuit is coupled between the other end of the ninth line and the output of the third amplifier. The first capacitor circuit includes a plurality of capacitors coupled in parallel between the other end of the sixth line and the output of the second amplifier. The second capacitor circuit includes a plurality of capacitors coupled in parallel between the other end of the ninth line and the output of the third amplifier. Each of the first capacitor circuit and the second capacitor circuit further includes a switching circuit configured to switch corresponding ones of the capacitors.

(Clause 10) In the power amplifier circuit according to clause 8, one end of the sixth line is coupled to the output of the second amplifier. One end of the ninth line is coupled to the output of the third amplifier. Another end of the sixth line and another end of the ninth line are configured to be supplied with a supply voltage. The power amplifier circuit further includes a first resonator circuit and a second resonator circuit. The first resonator circuit is coupled between the other end of the sixth line and a ground potential. The second resonator circuit is coupled between the other end of the ninth line and a ground potential. The first resonator circuit includes a plurality of LC series resonators coupled in parallel between the other end of the sixth line and the ground potential. The second resonator circuit includes a plurality of LC series resonators coupled in parallel between the other end of the ninth line and the ground potential. Each of the first resonator circuit and the second resonator circuit further includes a switching circuit configured to switch corresponding ones of the LC series resonators.

(Clause 11) In the power amplifier circuit according to any one of clauses 2 to 10, the first amplifier and the second amplifier are configured to implement, in combination, a Doherty amplifier, and the third amplifier and the fourth amplifier are configured to implement, in combination, another Doherty amplifier. The first amplifier and the fourth amplifier are configured to operate as carrier amplifiers. The second amplifier and the third amplifier are configured to operate as peaking amplifiers.

(Clause 12) In the power amplifier circuit according to any one of clauses 2 to 11, the first to fourth amplifiers are configured to implement a Doherty amplifier. The first amplifier is configured to operate as a carrier amplifier. The second to fourth amplifiers are configured to operate as peaking amplifiers.

(Clause 13) A transmit circuit according to an aspect includes the power amplifier circuit according to any one of Clauses 2 to 12, and a control circuit. The control circuit is configured to selectively drive, based on the power level of the input signal, the first to fourth amplifiers.

(Clause 14) A communication device according to an aspect includes the transmit circuit according to clause 13,a power supply circuit, a signal processing circuit, and a radiating element coupled to the output terminal. The power supply circuit is configured to control, based on the power level of the input signal, a supply voltage for driving the first to fourth amplifiers. The signal processing circuit is configured to generate the radio-frequency signal and supply the radio-frequency signal to the power amplifier circuit.

(Clause 15) In the communication device according to clause 14, the power supply circuit is configured to adjust, based on an envelope of the radio-frequency signal, the supply voltage to one of a plurality of discrete voltage levels.

The embodiments disclosed herein should be considered as examples in all respects and should not be interpreted as limiting. The scope of the present disclosure is indicated by the claims rather than the above descriptions of the embodiments, and all changes that come within the meaning and range of equivalency of the claims are therefore intended to be embraced therein.

### REFERENCE SIGNS LIST

1 communication device, 10, 10A-10C transmit circuit, 20 BBIC, 30 RFIC, 40 power supply circuit, 100, 100A-100C power amplifier circuit, 105 bias control circuit, 110 splitter, 120 phase shifter circuit, 131-133 preamplifier, 140 power amplifier stage, 141, 210 carrier amplifier, 142A-142C, 220 peaking amplifier, 134, 143A, 143B, 155, 230 phase shifter, 150A, 150B TLT, 151A-153A, 151B-153B, 161-163 line, 160, 160A converter circuit, 170A, 170B capacitor circuit, 171A, 171B, 181A, 181B switching circuit, 180A, 180B resonator circuit, 410 MPC, 420 power selection circuit, 430 digital ET, 1631, 1632 line section, ANT antenna, BS bias signal, C1-C5 capacitor, CON control signal, GND ground potential, N1, N2 connection node, Pin input signal, Pout output signal, SEL selection signal, T1, T3, T4, T10 input terminal, T2, T20 output terminal, TB1, TB2 balanced terminal, TR1-TR3 transformer, TR4 magnetically coupled transformer, VB battery voltage, Vcc supply voltage, Zc, Zpa, Zpb, Zpc impedance.

1. A power amplifier circuit comprising:
an input terminal;
a first amplifier, a second amplifier, a third amplifier, and a fourth amplifier, each configured to amplify an input signal that is a radio-frequency signal received through the input terminal and to be transmitted;
a first phase shifter, a second phase shifter, and a third phase shifter;
a converter circuit configured to convert a pair of balanced lines to an unbalanced line; and
an output terminal coupled to the unbalanced line, wherein the converter circuit has a first balanced terminal and a second balanced terminal that are respectively coupled to corresponding ones of the pair of balanced lines,
wherein the first phase shifter is coupled between an output of the first amplifier and an output of the second amplifier,
wherein the second phase shifter is coupled between an output of the third amplifier and an output of the fourth amplifier,
wherein the third phase shifter is coupled between the output of the second amplifier and the first balanced terminal,
wherein the output of the third amplifier is coupled to the second balanced terminal, and
wherein the second amplifier, the third amplifier, and the fourth amplifier are configured to be selectively driven based on a power level of the input signal.

2. The power amplifier circuit according to claim 1, wherein when the power level of the input signal is in a first range, the first amplifier, the second amplifier, the third amplifier, and the fourth amplifier are driven,
wherein when the power level of the input signal is in a second range that is lower than the first range, the first amplifier and the fourth amplifier are driven, while the second amplifier and the third amplifier are not driven, and
wherein when the power level of the input signal is in a third range that is lower than the second range, the first amplifier is driven, while the second amplifier, the third amplifier, and the fourth amplifier are not driven.

3. The power amplifier circuit according to claim 2, further comprising:
a splitter coupled to the input terminal, the splitter being configured to split the input signal received through the input terminal among the first amplifier, the second amplifier, the third amplifier, and the fourth amplifier with predetermined phase differences,
wherein phases of signals input to the first amplifier and the third amplifier lead a phase of a signal input to the second amplifier by 90°, and
wherein a phase of a signal input to the fourth amplifier leads the phase of the signal input to the second amplifier by 180°.

4. The power amplifier circuit according to claim 2, wherein the converter circuit is a magnetically coupled transformer.

5. The power amplifier circuit according to claim 2, wherein the converter circuit is a Marchand balun.

6. The power amplifier circuit according to claim 5, wherein the Marchand balun comprises:
a first line and a second line; and
a third line configured to couple with the first line and the second line,
wherein a first end of the first line is coupled to the first balanced terminal, and a second end of the first line is coupled to a ground potential,
wherein a first end of the second line is coupled to the second balanced terminal, and a second end of the second line is coupled to a ground potential,
wherein a first end of the third line is coupled to the output terminal, and a second end of the third line is an open end, and
wherein each of the first line and the second line has a line length of λ/4, and the third line has a line length of λ/2, λ being a wavelength of the radio-frequency signal.

7. The power amplifier circuit according to claim 2, further comprising:
a first transmission-line transformer coupled between the output of the second amplifier and the third phase shifter; and
a second transmission-line transformer coupled between the output of the third amplifier and the second balanced terminal.

8. The power amplifier circuit according to claim 7, wherein the first transmission-line transformer comprises:
a fourth line and a fifth line that are coupled in series between the third phase shifter and the output of the second amplifier; and
a sixth line configured couple with the fourth line and the fifth line, and
wherein the second transmission-line transformer comprises:
a seventh line and an eighth line that are coupled in series between the second balanced terminal and the output of the third amplifier; and
a ninth line configured to couple with the seventh line and the eighth line.

9. The power amplifier circuit according to claim 8, wherein a first end of the sixth line is coupled to the output of the second amplifier,
wherein a first end of the ninth line is coupled to the output of the third amplifier,
wherein a second end of the sixth line and a second end of the ninth line are supplied with a supply voltage,
wherein the power amplifier circuit further comprises:
a first capacitor circuit coupled between the second end of the sixth line and the output of the second amplifier; and
a second capacitor circuit coupled between the second end of the ninth line and the output of the third amplifier, wherein the first capacitor circuit comprises a plurality of capacitors coupled in parallel between the second end of the sixth line and the output of the second amplifier,
wherein the second capacitor circuit comprises a plurality of capacitors coupled in parallel between the second end of the ninth line and the output of the third amplifier, and
wherein each of the first capacitor circuit and the second capacitor circuit further comprises a switching circuit configured to switch corresponding ones of the capacitors.

10. The power amplifier circuit according to claim 8, wherein a first end of the sixth line is coupled to the output of the second amplifier,
wherein a first end of the ninth line is coupled to the output of the third amplifier,
wherein a second end of the sixth line and a second end of the ninth line are supplied with a supply voltage,
wherein the power amplifier circuit further comprises:
a first resonator circuit coupled between the second end of the sixth line and ground; and
a second resonator circuit coupled between the second end of the ninth line and ground,
wherein the first resonator circuit comprises a plurality of LC series resonators coupled in parallel between the second end of the sixth line and ground,
wherein the second resonator circuit comprises a plurality of LC series resonators coupled in parallel between the second end of the ninth line and ground, and
wherein each of the first resonator circuit and the second resonator circuit further comprises a switching circuit configured to switch corresponding ones of the LC series resonators.

11. The power amplifier circuit according to claim 2, wherein the first amplifier and the second amplifier, in combination, constitute a first Doherty amplifier, wherein the third amplifier and the fourth amplifier, in combination, constitute a second Doherty amplifier,
wherein the first amplifier and the fourth amplifier are carrier amplifiers, and
wherein the second amplifier and the third amplifier are peaking amplifiers.

12. The power amplifier circuit according to claim 2, wherein the first amplifier, the second amplifier, the third amplifier, and the fourth amplifier, in combination, constitute a Doherty amplifier,
wherein the first amplifier is a carrier amplifier, and
wherein the second amplifier, the third amplifier, and the fourth amplifier are peaking amplifiers.

13. A transmit circuit comprising:
the power amplifier circuit according to claim 2; and
a control circuit configured to selectively drive, based on the power level of the input signal, the first amplifier, the second amplifier, the third amplifier, and the fourth amplifier.

14. A communication device comprising:
the transmit circuit according to claim 13;
a power supply circuit configured to control, based on the power level of the input signal, a supply voltage for driving the first amplifier, the second amplifier, the third amplifier, and the fourth amplifier;
a signal processing circuit configured to generate the radio-frequency signal and supply the radio-frequency signal to the power amplifier circuit; and
a radiating element coupled to the output terminal.

15. The communication device according to claim 14, wherein the power supply circuit is configured to adjust, based on an envelope of the radio-frequency signal, the supply voltage to one of a plurality of discrete voltage levels.
